(19) United States
(12) Patent Application Publication
(10) Pub. No.: US 2025/0181055 A1
(43) Pub. Date: Jun. 5, 2025

(54) METHODS AND SYSTEMS FOR PROVIDING SHORT STRUCTURES FOR BACKDRILL VALIDATION

(71) Applicant: CIENA CORPORATION, Hanover, MD (US)

(72) Inventors: Vinh Ha, Nepean (CA); Michael Ledwinka, Ottawa (CA)

(73) Assignee: CIENA CORPORATION, Hanover, MD (US)

(21) Appl. No.: 18/526,129

(22) Filed: Dec. 1, 2023

(51) Int. Cl. G05B 19/4097; G05B 19/404; G05B 19/414; H05K 3/00; H05K 3/42

(52) U.S. Cl. CPC G05B 19/4097; G05B 19/404; G05B 19/4147; H05K 3/0005; H05K 3/0047; H05K 3/421; H05K 3/429; G05B 2219/45026; G05B 2219/45035; H05K 2203/0207; H05K 2203/163

(57) ABSTRACT

Aspects of the subject disclosure may include, for example, receiving a command to embed, in supplementary data, information regarding one or more trace elements for one or more locations in a layer for a printed circuit board (PCB), and generating output data for facilitating fabrication and post-processing of the PCB, wherein the output data includes the supplementary data, and wherein the supplementary data enables the one or more trace elements to be formed in the layer during the fabrication of the PCB and leveraged during the post-processing of the PCB. Other embodiments are disclosed.

### FIELD OF THE DISCLOSURE

The subject disclosure relates to methods and systems for embedding short structure(s) for facilitating backdrilling during printed circuit board (PCB) post-processing.

### BACKGROUND

A PCB is used to route signals between electrical and electronic components that are connected to or fabricated/mounted on the board. PCBs are primarily composed of layers of dielectric material and conductive material, where conductive traces are formed to provide electrical connectivity between the components. A PCB has two opposing external surfaces, one or both of which may bear circuitry. Circuitry may include any form of electrical or electronic components, including analog components, digital components, ground planes, and simple conductors, such as copper or other conductive traces. A multilayer PCB may include one or more layers of circuitry disposed between the two opposing external major surfaces. The process of creating a PCB involves various phases, including planning, design, fabrication, post-processing, and assembly.

### BRIEF DESCRIPTION OF THE DRAWINGS

Reference will now be made to the accompanying drawings, which are not necessarily drawn to scale, and wherein:

FIG. 1A shows a high-level process of PCB design using a PCB design system/tool and fabrication by a PCB fabricator in accordance with various aspects described herein.

FIGS. 1B to 1D illustrate the progression from PCB design to backdrilling in accordance with an existing PCB design, fabrication, and post-processing procedure.

FIGS. 2A and 2B illustrate the progression from PCB design to backdrilling in accordance with an example, non-limiting PCB design, fabrication, and post-processing procedure.

FIGS. 2C and 2D illustrate an example, non-limiting embodiment of a method for creating and embedding short structure(s) for facilitating backdrilling, in accordance with various aspects described herein.

FIG. 2E illustrates an example, non-limiting embodiment of another method for creating and embedding short structure(s) for facilitating backdrilling, in accordance with various aspects described herein.

FIG. 3A depicts an illustrative embodiment of a method in accordance with various aspects described herein.

FIG. 3B depicts an illustrative embodiment of a method in accordance with various aspects described herein.

FIG. 4 is a block diagram of an example, non-limiting embodiment of a computing environment in accordance with various aspects described herein.

### DETAILED DESCRIPTION

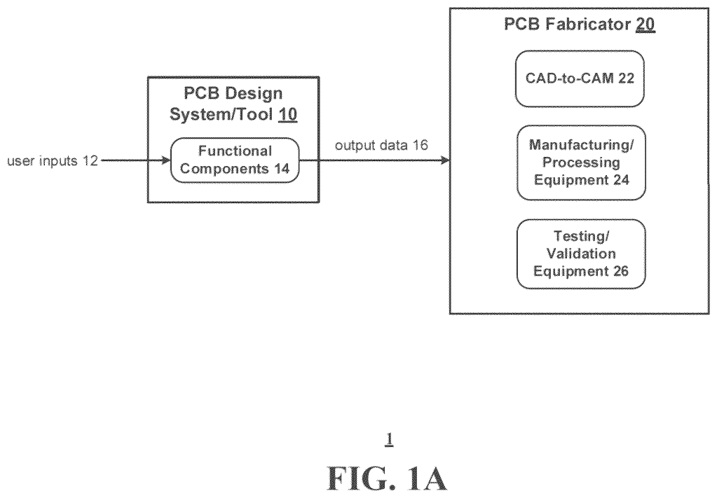

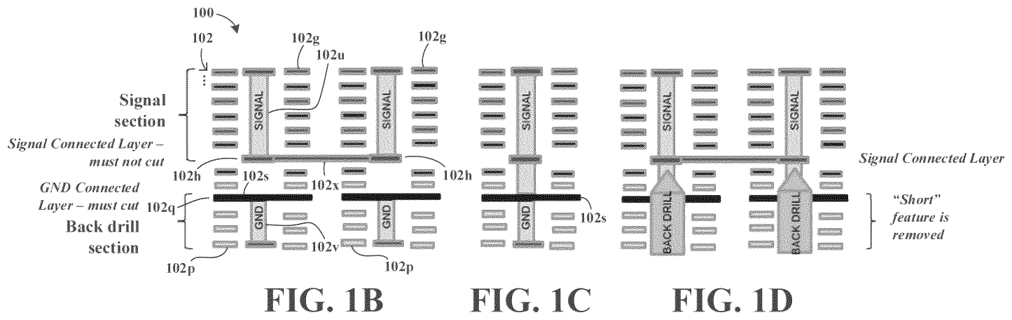

FIG. 1A shows a high-level process 1 of PCB design using a PCB design system/tool 10 and fabrication by a PCB fabricator 20 in accordance with various aspects described herein. The PCB design system/tool 10 may be an electronic design automation (EDA) system or a computer-aided design (CAD) system. The PCB fabricator 20 may correspond to one or more entities (e.g., a manufacturer, a fabrication shop, or the like) that are equipped to produce PCBs.

The PCB design system/tool 10 may provide graphical editing tools (via a graphical user interface (GUI)) for user control over the PCB design process. As shown in FIG. 1A, the PCB design system/tool 10 may include functional components 14 that can operate on user inputs 12 and provide output data 16. Functional components 14 may include various integrated components that facilitate the design and manufacturing of PCBs. For instance, the PCB design system/tool 10 may include schematic design/capture functionality that enables users to create schematics of circuits via manipulation of symbols, connections, etc. As another example, the PCB design system/tool 10 may include component management/libraries for managing data regarding components/devices and predefined component footprints to be used on PCB layouts. As yet another example, the PCB design system/tool 10 may include PCB layout design functionality that enables users to design the physical layout of the PCB via creation of artwork (e.g., etch patterns) for each layer of the PCB. PCB layout design may involve layer creation (e.g., classes of layers, subclasses of layers, etc.), layer stack-up specifications, component footprint designs that define characteristics or attributes of pads (“padstack”), component placements, via placements, trace routing, drill/tooling hole placements, solder mask designs, silkscreen designs, surface finish designs, design rule specifications that outline constraints/tolerances/requirements, etc.

In various embodiments, the PCB design system/tool 10 may enable users to add or include supplementary data that is related to but distinct from content in the actual PCB layers. Supplementary data may include any information that might facilitate a fabricator in the PCB fabrication process. For instance, supplementary data may include annotations regarding the PCB design, such as design notes, drawings, assembly instructions, reference designation information, revision history information, test or probe points/locations data, or the like. In this case, the supplementary data may be included in an annotation or documentation layer or the like. As another example, supplementary data may include film records (e.g., film positives and/or film negatives) or film layers associated with the PCB layers and/or components designed thereon. Film records may facilitate the photolithography process as well as the creation of stencils or masks that are used in solder mask application, etching, silkscreen printing, or the like. By virtue of its separation from actual content in the design of PCB layers, supplementary data is not included in and does not impact the actual artwork of the PCB layers.

In various embodiments, the PCB design system/tool 10 may include design rule check (DRC) functionality that checks PCB designs against defined rules/constraints, simulation/analysis functionality for analyzing signal performance, thermal characteristics, etc., and visualization/modeling functionality that provides users with two-dimensional (2D) and/or three-dimensional (3D) views of the PCB design.

In one or more embodiments, the PCB design system/tool 10 may include data generation/export functionality for providing the output data 16. The output data 16 may include any fabrication data that allows the PCB fabricator 20 to fabricate the designed PCB. This may include design data for the layers of the PCB, supplementary data, and/or other types of data, such as bill of materials (BOM) information, via backdrilling information (depths, locations, etc.) as may be inputted using a backdrilling utility function of the PCB design system/tool 10, and so on. In various embodiments, the output data 16 may be in a format that the PCB fabricator 20 (e.g., CAD-to-computer aided manufacturing (CAM) system 22) can utilize for fabrication. As some examples, the output data 16 may be in one or more files that are in the Open Database (ODB) or ODB++ format, one or more Gerber files, one or more Portable Document Format (PDF) files, one or more Graphics Interchange Format (GIF) files, one or more Joint Photographic Experts Group (JPEG) files, one or more Tagged Image File Format (TIFF) files, one or more Bitmap Image (BMP) files, and/or one or more other types of 2D/3D CAD-generated files. ODB++ files, in particular, may include Gerber data needed to create a PCB, such as artwork that defines the various elements on each PCB layer (e.g., copper traces, pads, vias, solder mask openings, silkscreen markings, etc.). ODB++ files may include additional data, such as layer stack-ups, component placement data, netlist(s) (or list(s) of nets—i.e., connections between components), component libraries, design rules, drill files (for specifying locations and sizes of holes to be drilled), and so on. ODB++ files may also include supplementary data, such as annotation or documentation layer data, film records, and/or the like. It will be understood and appreciated that the PCB design system/tool 10 may include other functionalities not described above but that relate to or facilitate overall PCB design, fabrication, post-processing, etc.

As shown in FIG. 1A, the PCB fabricator 20 may be equipped with a CAD-to-CAM system 22, manufacturing/processing equipment 24, and testing/validation equipment 26. Some or all of these systems/equipment may operate autonomously or based at least in part on administrator control. The CAD-to-CAM system 22 may process output data 16 to convert it into a format that the manufacturing/processing equipment 24 can utilize to fabricate the PCB. The manufacturing/processing equipment 24 may include a variety of devices or apparatuses, including, but not limited to, film plotters, lamination presses, drilling/milling/routing machines, pick-and-place machines, via plating devices, chemical processors, solder mask and silkscreen printing machines, surface mount technology (SMT) machines, post-processing machines (e.g., for backdrilling, etc.), and so on. The testing/validation equipment 26 may include, but not be limited to, optical inspection devices, in-circuit test machines, cleaning machines, electrical test equipment, and so on.

Vias are commonly used to connect signals between layers of a PCB. More particularly, a via is a hole that is drilled or otherwise formed in a PCB between any two layers, and that is plated or filled with copper or other conductive material. For ease of fabrication, vias are typically drilled completely through the PCB even if the via is used to connect circuitry on two internal layers or to connect circuitry on one of the two external layers (topmost layer or bottommost layer) and an internal layer. While vias are useful for such interconnection, they can exhibit a change point in signal flow that causes signal degradation, particularly with respect to signals in the radio and microwave frequency range (e.g., frequencies over 100 megahertz (MHz)). Vias are generally capacitive to high frequency signals, where longer vias have higher capacitance and thus cause greater signal degradation. This problem is particularly acute with vias that are used for connectors due to the requirement for close spacing (usually standardized) for proper mating with connector pins of a plug-in card. Also, backplanes on which such connector vias are commonly found tend to be rather thick PCBs because they generally must accommodate a large number of layers due to the need to route a large number of signals over the PCB. Accordingly, it is common practice in PCB fabrication to drill vias completely through the PCB, plate the entire via with copper or another conductive material, and then counterbore (or backdrill) the vias to remove the unnecessary copper therein. The unnecessary copper in any given via (also referred to as the via stub) is the copper that runs between any layers of the PCB that are not being electrically interconnected by that via. For instance, if a particular via is provided to interconnect the topmost external layer with the second topmost, internal layer of the PCB, then the via would be counterbored from the bottommost external layer up to but just short of the second topmost layer. From a design perspective, through-hole vias may be generally represented in the form of a design netlist that is exported in output data. The output data may also include fabrication data (e.g., CAM data (ODB+)), which may include design data representing the design and supplementary data, such as film records, data regarding backdrill locations, drill depths, etc. The fabricator may generate its own version of the netlist using the received fabrication data and compare it with the received design netlist. A match would indicate that there are no connectivity issues in the design, such as signals that are shorted to ground (essentially, that the design netlist matches the design as represented in the fabrication data).

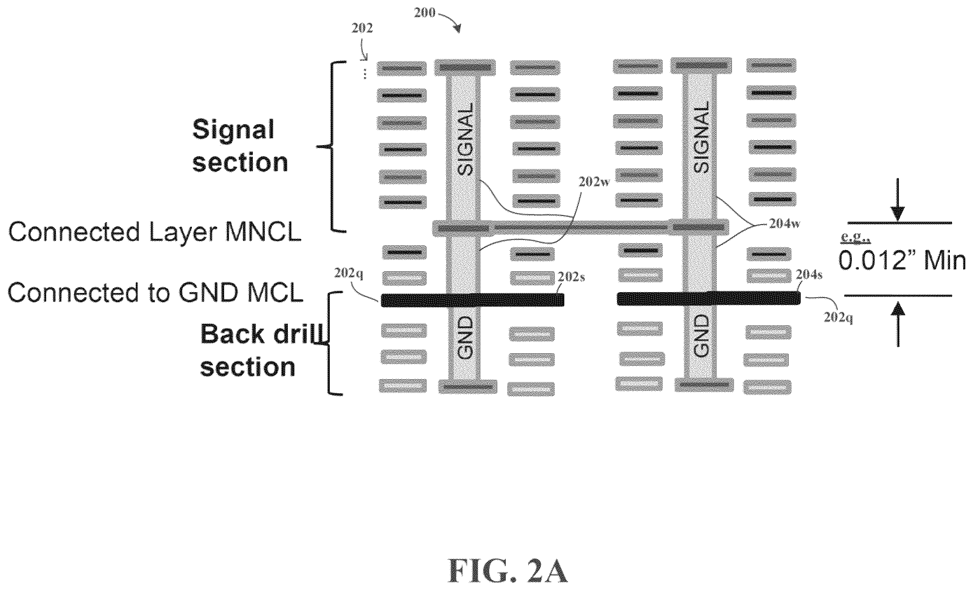

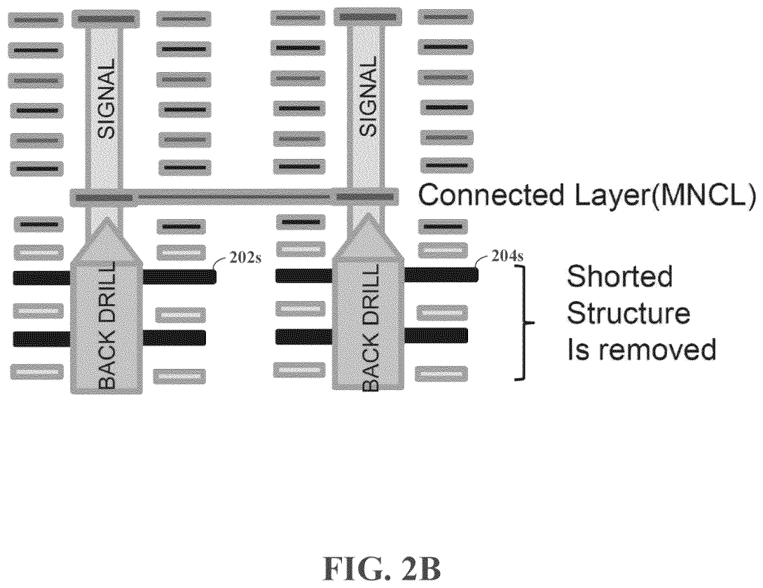

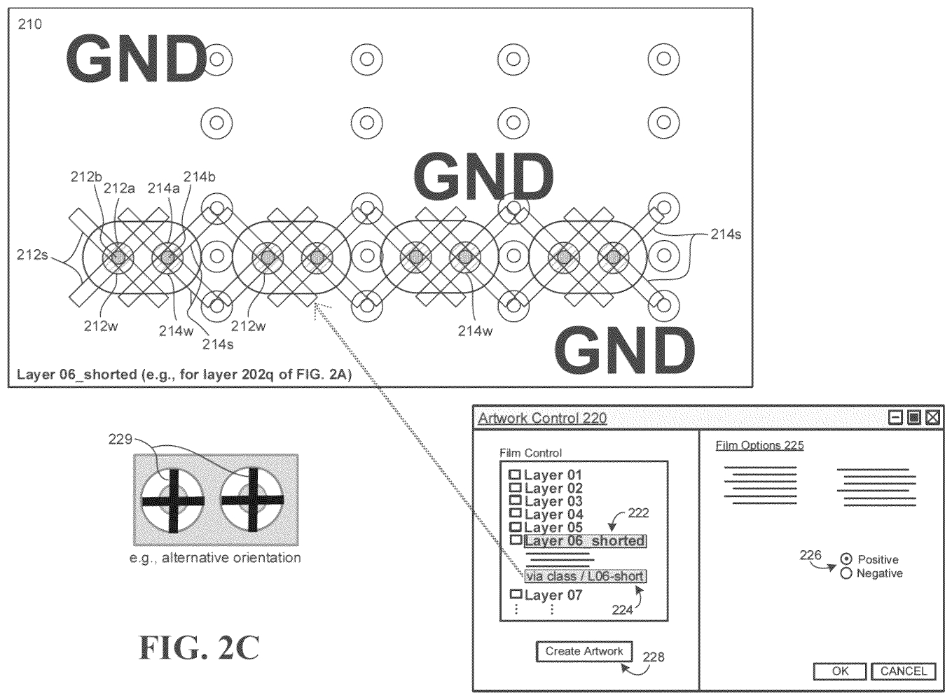

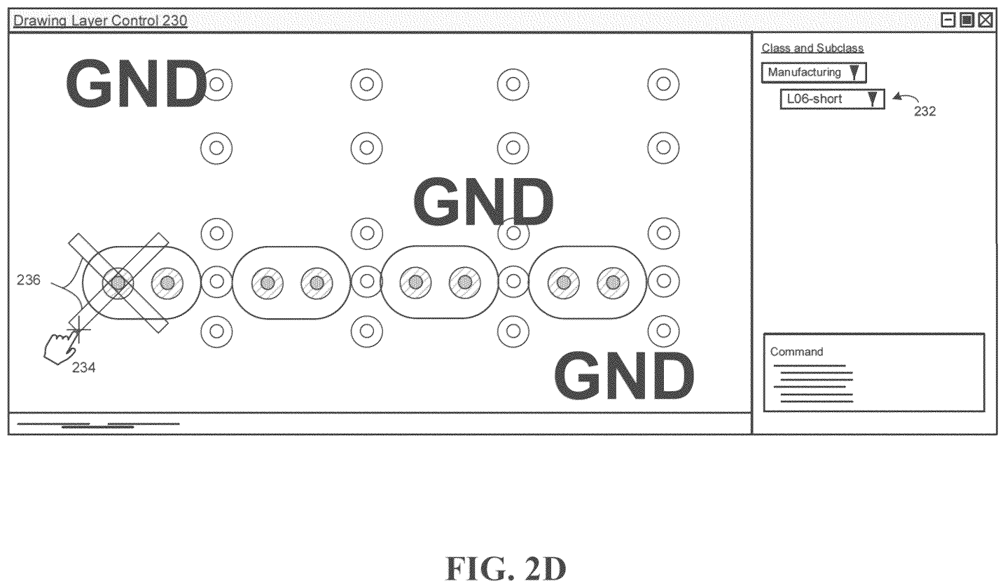

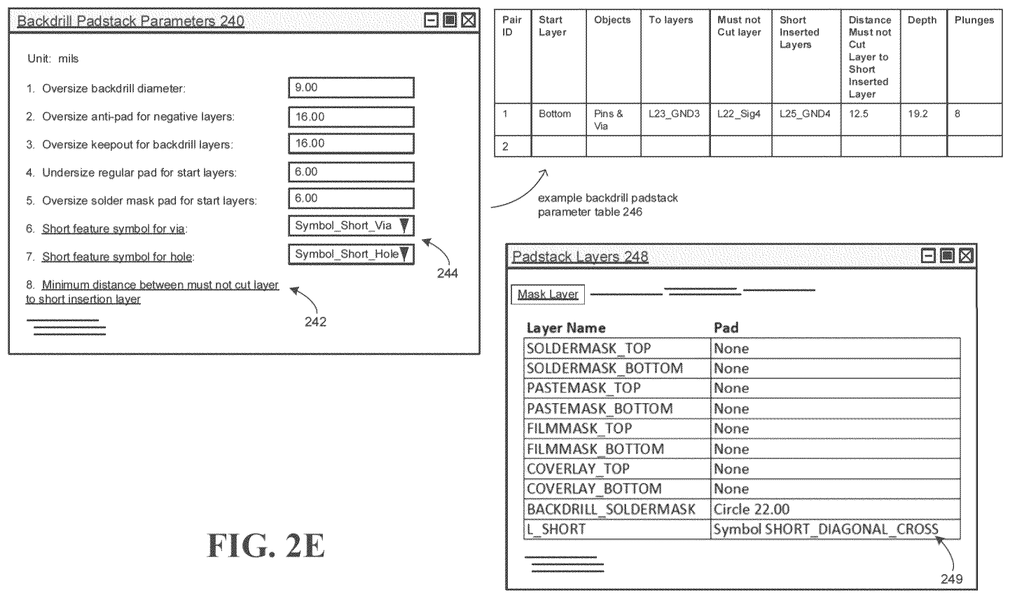

Twardy et al. U.S. Pat. No. 8,431,834 entitled “Method For Assuring Counterbore Depth Of Vias On Printed Circuit Boards And Printed Circuit Boards Made Accordingly” (hereafter Twardy), which is incorporated herein by reference in its entirety, describes techniques for facilitating the backdrilling process. FIGS. 1A and 1B of Twardy illustrate a conventional via before and after counterboring, where, after the via is formed, it is counterbored by drilling with a drill (that has a larger diameter than the via) from the bottom surface up to, but just short of, a signal layer of interest. While this counterboring eliminates almost all of the copper in the via between the bottom layer and the signal layer, there is generally some copper left below the signal layer due to drilling tolerances. It can readily be detected if the drill drills too far by simple resistive testing. However, it is much more difficult to determine if the drill did not drill as deeply as desired, which, again, can lead to undesired signal degradation. FIGS. 2A and 2B of Twardy illustrate an example solution to this problem by introducing a trace (i.e., a short structure or feature) that is coupled to a ground layer just underneath the signal layer of interest, and that is intended to be destroyed during the counterboring process. If the counterbore does not at least reach the ground layer, then the trace will remain in that layer, shorting the via to ground. On the other hand, if the counterbore at least reaches the ground layer, then at least a portion of the trace will be destroyed as a result, thereby disrupting the electrical connection between the via and ground. An impedance test that shows such a short circuit would indicate that the counterbore has not been drilled deep enough. However, the moment that the impedance test reveals an open circuit would indicate that the counterbore has been drilled to a reasonable depth.

While it might be possible to include, in the PCB design, a short structure (such as that described in Twardy) for a through-hole via that is to be backdrilled in post-processing, this can result in a DRC error since the signal layer of interest would be connected to ground. One technique to address this issue will now be discussed with respect to FIGS. 1B to 1D herein. FIGS. 1B to 1D illustrate the progression from PCB design to backdrilling in accordance with an existing PCB design, fabrication, and post-processing procedure. In particular, the procedure leverages technique(s) described in Twardy, particularly the inclusion of a short structure (or trace element) in the PCB design data to facilitate backdrilling. As depicted in FIG. 1B, the PCB design may provide for a multilayer PCB 100 that includes various conductive layers 102 (e.g., composed of copper or other conductive material), including a top signal layer 102g, an inner signal layer 102h, a bottom ground layer 102p, an inner ground layer 102q, as well as other layers (e.g., for power, signals, ground, etc.). Although not shown, the design may also include dielectric layer(s) that occupy spaces between the conductive layers. Vias 102u and 102v may be mirrored blind vias that each penetrates from an exterior layer and end at an interior layer. Any ground layers that might exist between signal layers 102g and 102h may generally be complete sheets of material (e.g., copper) that substantially occupy the entire respective layers except for areas surrounding the via 102u, since, generally, each via forms part of a signal path between two electronic components and, therefore, should not be shorted to ground. These unoccupied areas around the via 102u are commonly called anti-pads. There may be a pad in the signal layer 102g that is formed around and in contact with (e.g., copper) plating of the via 102u so as to make electrical contact therewith. Similarly, there may be a pad in the signal layer 102h that is formed around and in contact with (e.g., copper) plating of the via 102u so as to make electrical contact therewith—e.g., for coupling signal trace 102x to the via 102u. In theory, signal lines, such as trace 102x, can be extended right up to a via, and pad(s) may not be needed. However, the use of pads allows for more lenient manufacturing tolerances. Although not shown, the via 102u may couple to a connector that provides a signal to the pad (e.g., via a press fit pin of the connector) to the signal path 102x in the signal layer 102h.

As shown in FIG. 1B, a structure 102s may be designed into the ground layer 102q, which is coupled to ground by way of the blind via 102v. The design of mirrored blind vias 102u and 102v, as opposed to a single through-hole via, advantageously overcomes the above-described DRC error issue, since the signal layer of interest (102h) would not be connected to ground by virtue of the separation of the two blind vias. That is, there is no connectivity between the signal layer 102h and the short structure 102s. As depicted, the signal section from layer 102g to layer 102h may be considered “must not cut layers” (MNCL) whereas the layers from layer 102q to layer 102p may be considered “must cut layers” (MCL) that are to be backdrilled out. The design netlist for such a configuration may be output to a fabricator with no netlist issues. However, it is possible that a PCB design system/tool would not recognize mirrored blind vias as being backdrillable, and thus prohibit the defining of backdrilling specifications for such vias. In this situation, the PCB designer might be required to perform an initial PCB design with through-hole vias rather than mirrored blind vias, output the backdrilling data based on this initial PCB design, and then redo the design by substituting (whether manually or by way of a custom script) each to-be-backdrilled through-hole via with mirrored blind vias and also adding the appropriate short structure(s), such as short structure 102s. The fabricator may produce the PCB based on the redone design (i.e., the one with mirrored blind vias and the short structure(s)), perform (FIG. 1C) post-processing drilling as if the mirrored blind vias were a single standard through-hole via, perform via plating (which would result in a connection of the via to ground by way of the short structure 102s), and subsequently perform backdrilling (FIG. 1D) to the appropriate depth by leveraging resistive testing to monitor for the removal of the short structure 102s.

While the process described above with respect to FIGS. 1B to 1D leverages the beneficial short structure for facilitating backdrilling, it can be cumbersome to designers as well as intrusive to the design database. For instance, if there any changes that need to be made after backdrilling data generation and design output, all of the mirrored blind vias need to be reverted back to through-hole vias in the design in order to re-generate the backdrilling data and all of the through-hole vias need to be re-substituted with mirrored blind vias again for design output. Further, since the fabricator will fabricate the PCB based on the redone design (i.e., the one with mirrored blind vias), additional instructions need to be provided to the fabricator to treat those mirrored blind vias as through-hole vias during post-processing. Otherwise, the fabricator may drill the mirrored blind vias as they are shown in the received design.

The subject disclosure describes illustrative embodiments of a method for embedding short structure(s) for facilitating backdrilling during PCB post-processing. In exemplary embodiments, one or more short structures may be defined in supplementary data associated with PCB layer(s) that is distinct from the actual artwork of such layer(s). In various embodiments, the supplementary data may be an additional film layer, such as a film record that is associated with the artwork of a PCB layer. Leveraging such supplementary data to “merge” short structure(s) into output data (e.g., ODB++ files), without the short structure(s) actually appearing in or affecting the artwork of the PCB layer design, avoids the aforementioned problem of DRC errors during the design/check process, since there are no short structure(s) in the actual design of the PCB layer(s) themselves and thus no issues in the design netlist. Through-hole vias (rather than mirrored blind vias) can thus be used in the overall design, which advantageously allows for the use of backdrill utility functionality of the PCB design system/tool to define backdrill data.

Although the short structure(s) are not actually included in the PCB design, the fabricator will nevertheless recognize the presence of such short structure(s) based on an analysis of the film record(s), and will create such structure(s) during PCB layer fabrication. Without other supplemental information, the fabricator may, in generating its own version of the netlist according to received fabrication data, identify a mismatch between its generated netlist and the received design netlist. Thus, in exemplary embodiments of the method, a supplemental instruction or guide may be (e.g., generated and) provided to the fabricator that properly identifies the nets to be backdrilled (i.e., nets corresponding to the short structure(s)) so as to enable the fabricator to resolve the mismatch. The supplemental instruction or guide would thus serve as backdrill data for the fabricator. In this way, the fabricator can recognize with certainty that short structure(s) are to be fabricated at nets that are to be backdrilled.

In exemplary embodiments, short structure(s) may be embedded or included in film records without a need to modify padstacks in the PCB design. In some embodiments, short structure(s) may alternatively be defined in a film layer that is associated with padstack design data. Various details of this alternative implementation are described below.

Exemplary embodiments of the method described herein simplify the backdrilling process as compared to cases where the process in FIGS. 1B to 1D is employed. For instance, the fabricator would not need to be separately provided with additional drilling/backdrilling instructions to drill particular mirrored blind vias as through-hole vias and possibly undergo unnecessary PCB tooling changes as a result. Rather, by embedding short structure(s) in output data by way of supplementary data (e.g., film records) and not in the actual PCB layer designs, the structure(s) can nevertheless be recognized by a fabricator for inclusion in PCB fabrication. Providing the fabricator with a supplemental instruction or guide that essentially serves as backdrill data enables the fabricator to easily reconcile the backdrill nets with the short structure(s). The fabricator can thus interpret Gerber data without issue, fabricate the PCB with the short structure(s), drill the vias as designed (i.e., as through-hole vias), plate them in post processing, and perform the appropriate backdrilling by leveraging the short structure(s), all while retaining backdrill attributes. Exemplary embodiments of the method described herein provide an affordable solution for backdrilling that can be employed for back panel PCBs and line cards alike.

Various embodiments may also provide for improved backdrill validation, which allows the fabricator to employ netlist testing to achieve improved (e.g., 100%) test coverage on all backdrill holes. This enables design requirements for signal integrity to be easily met, thereby improving product quality. Fewer to no backdrill errors also provides significant PCB assembly trunking cost savings. Of course, in cases where backdrilling is insufficient to destroy the short structure(s), additional processing, such as further drilling or other type(s) of processing, may be performed to remove the short structure(s).

One or more aspects of the subject disclosure include a device, comprising a processing system including a processor, and a memory that stores executable instructions that, when executed by the processing system, facilitate performance of operations. The operations may include receiving a command to embed, in supplementary data, information regarding one or more trace elements for one or more locations in a layer for a printed circuit board (PCB), and generating output data for facilitating fabrication and post-processing of the PCB, wherein the output data includes the supplementary data, and wherein the supplementary data enables the one or more trace elements to be formed in the layer during the fabrication of the PCB and leveraged during the post-processing of the PCB.

One or more aspects of the subject disclosure include a non-transitory machine-readable medium, comprising executable instructions that, when executed by a processing system including a processor, facilitate performance of operations. The operations may include receiving a command to embed, in supplementary data, information regarding one or more trace elements for one or more locations in a layer for a printed circuit board (PCB), and generating output data for facilitating fabrication and post-processing of the PCB, wherein the output data includes the supplementary data, and wherein the supplementary data enables the one or more trace elements to be formed in the layer during the fabrication of the PCB and leveraged during the post-processing of the PCB.

One or more aspects of the subject disclosure include a method. The method may include receiving, by a processing system including a processor, a command to embed, in supplementary data, information regarding one or more trace elements for one or more locations in a layer for a printed circuit board (PCB), and generating, by the processing system, output data for facilitating fabrication and post-processing of the PCB, wherein the output data includes the supplementary data, and wherein the supplementary data enables the one or more trace elements to be formed in the layer during the fabrication of the PCB and leveraged during the post-processing of the PCB.

One or more aspects of the subject disclosure include a method. The method may include obtaining output data for facilitating fabrication and post-processing of a printed circuit board (PCB), wherein the output data comprises supplementary data that includes information regarding one or more trace elements for one or more locations in a layer for the PCB. The method may further include causing the one or more trace elements to be formed in the layer during the fabrication, and leveraging the one or more trace elements during the post-processing.

One or more aspects of the subject disclosure include a printed circuit board (PCB). The PCB may comprise one or more trace elements formed in one or more locations in a layer of the PCB, the PCB being fabricated in accordance with output data that includes supplementary data, the supplementary data identifying the one or more trace elements to be formed in the one or more locations in the layer, and the one or more trace elements being usable to facilitate post-processing of the PCB.

FIGS. 2A and 2B illustrate the progression from PCB design to backdrilling in accordance with an example, non-limiting PCB design, fabrication, and post-processing procedure. As depicted in FIG. 2A, the PCB design may, similar that described above with respect to FIG. 1B, provide for a multilayer PCB 200 that includes various conductive layers 202. The difference here is that through-hole vias 202w, 204w that each extends from exterior layer to exterior layer may be defined instead of mirrored blind vias like that in FIG. 1B. Although FIG. 2A shows short structures 202s, 204s (similar to the short structure(s) 102s of FIG. 1B), the short structures 202s, 204s may not be explicitly included in the design of the multilayer PCB 200. That is, the short structures 202s, 204s may not be included in artwork of the layer 202q and thus may not be accounted for in the resulting design netlist. Instead, the short structures 202s, 204s may be defined in supplementary data, such as one or more film record(s) associated with the layer 202q. Film records may document the components that make up the associated layer. Including such short(s) in supplementary data, rather than in the actual design, avoids DRC short circuit errors during the design process. Further, designing the vias as through-hole vias also allows for the use of any backdrilling utility that the PCB design software/tool may offer. The output data (e.g., ODB++ file or the like) of the PCB design software/tool may include a design netlist that is based on the design of the layer 202q, and may also include fabrication data as well as the supplementary data (e.g., film record(s)), which the fabricator may leverage to identify the locations of the shorts. In exemplary embodiments, a supplemental instruction or guide may further be generated and included in the output data (or otherwise separately provided) for use by the fabricator as part of its comparison processing, which can help the fabricator recognize that the inserted shorts are intentional and are to be drilled out during backdrilling. In this way, the fabricator can perform the fabrication in accordance with the received fabrication data, with shorts created as identified in film record(s), rather than based on the received design netlist. In some embodiments, the fabricator's CAD-to-CAM system 22 and/or an associated system or tool may be configured to automatically resolve mismatches between the fabricator's generated netlist and the received design netlist by referring (e.g., based on the supplemental instruction or guide) to the received fabrication data as the “master” source for the PCB fabrication. In any case, with those shorts in place, resistive (or netlist electrical) testing can be performed therewith during backdrilling to facilitate proper removal of the must cut layer and the short structures 202s, 204s (FIG. 2B). Such netlist electrical testing can provide coverage for backdrill holes (e.g., 100% coverage for all backdrill holes), which simplifies the validation of backdrill depths for the holes. It is to be understood and appreciated that, although two vias and two short structures are shown in FIGS. 2A and 2B, the multilayer PCB 200 may include more or fewer vias and/or more or fewer short structures.

FIGS. 2C and 2D illustrate an example non-limiting embodiment of a method for creating and embedding short structure(s) for facilitating backdrilling, in accordance with various aspects described herein. It is to be understood and appreciated that various user interfaces shown in FIGS. 2C and 2D are merely exemplary and that different manners of receiving user inputs and presenting user selectable options can implemented. FIG. 2C shows a portion of an example film record 210 of a PCB layer (Layer 06-shorted). As depicted, the layer may be a ground layer that includes various vias, including pairs of vias 212w, 214w with corresponding via barrels 212b, 214b and anti-pads 212a, 214a. As also shown in FIG. 2C, an artwork control interface 220 (of the PCB design system/tool) may enable a user to configure film control options. Here, the control interface 220 may enable a graphic of a short structure (“L06-short” 224, which can be drawn or defined in any suitable manner, such as in a drawing layer for a manufacturing subclass or the like, described in more detail below) to be added (222) as elements (212s, 214s) in the film record of the layer. Doing so does not result in the short structure(s) being added to the actual artwork design of the layer, but may instead cause the short structure(s) to be embedded as element(s) in the associated film record. As shown in FIG. 2C, other film control options 225 may include choice of film positive/negative (226) as well as the instruction to create artwork (228) based on the selected film options. Creation of artwork may, for instance, cause not only the actual artwork of the layer to be generated/output, but also the film record for the layer as well as. It is to be understood and appreciated that, although multiple pairs of vias and pairs of short structures are shown in FIG. 2C, more or fewer vias, more or fewer pairs of vias, more or fewer short structures, and/or more or fewer pairs of short structures may be included in a film record. Furthermore, although the short structures 212s, 214s are shown in FIG. 2C as “X” shapes or crosses in particular orientation(s), other orientations (e.g., reference number 229) and/or other shapes or combinations of shapes are possible.

Referring to FIG. 2D, a drawing layer control interface 230 may enable creation of graphics, in a drawing layer, that correspond to elements, such as short structures. As depicted, the drawing layer may be associated with a subclass within a design class (232). A user may define or otherwise draw graphic(s) as desired, none of which will actually be included in the design of any PCB layer. Here, graphic 236, corresponding to a short structure, may be drawn (234) in the drawing layer. This subclass graphic can then be called upon or included/added to a film record for a PCB layer, as discussed above with respect to FIG. 2C. In this way, short structure(s) can be merged into film record processing to be etched into the actual physical PCB layer during fabrication, advantageously facilitating backdrilling depth control.

In certain embodiments, short structure(s) may alternatively be defined in a backdrill film layer that is associated with a padstack. A padstack refers to the set of design parameters and properties that are associated with one or more pads on a PCB. A padstack may include various information about a pad, such as, for instance, type, shape, dimensions, annular ring, anti-pad, thermal relief, mask opening, drilling data, etc. An existing “backdrill replace” technique for implementing the process described above with respect to FIGS. 1B to 1D involves padstack substitution for each location that is to be backdrilled, where a padstack that is partial on one exterior layer (for one blind via of a mirrored blind via pair) and another padstack that is partial on the opposite exterior layer (for the other blind via of the mirrored blind via pair) are created manually or using an automated script, and where nets are then assigned to all of the padstacks. One limitation of this technique is that backdrill parameters are lost after the padstack substitution. Furthermore, the technique is generally applicable to backplanes and not line cards.

FIG. 2E illustrates an example non-limiting embodiment of a method for creating and embedding short structure(s) for facilitating backdrilling, in accordance with various aspects described herein. It is to be understood and appreciated that various user interfaces shown in FIG. 2E are merely exemplary and that different manners of receiving user inputs and presenting user selectable options can implemented. As depicted in FIG. 2E, a backdrill padstack parameters interface 240 may include user selectable option(s) (e.g., drop down menu(s) or otherwise) that enable a user to include or embed short structure(s). These option(s) may, for instance, include option(s) (244) for selecting graphic(s) of short structure(s) (e.g., which may include dimension(s), such as isothermal spoke width for specifying the trace width of the short structure) as well as option(s) for specifying the minimum distance between a must not cut layer and selected short insertion layers. The graphic(s) of short structure(s) may be created in a manner similar to that described above with respect to FIG. 2D. In one or more embodiments, the PCB design system/tool may update a backdrill padstack parameter table (e.g., table 246) based on the selected options. More importantly, a backdrill film layer (see padstack layers interface 248) may also be created for the padstack based on the selected options-here, shown as film layer “L_SHORT” in which diagonal-cross shaped short structure(s) are to be used for backdrill via(s)/hole(s). The advantages of this exemplary method are that it is much less invasive to the PCB layer design database and can be applied to backplanes as well as line cards. Of course, it nevertheless involves deviation from the library elements of the PCB design system/tool. One skilled in the art would understand and appreciate that short structure(s) introduced in the manner described with respect to FIG. 2E are analogous to the above-described film record embedding technique, in that the short structure(s) are only added to supplementary data (e.g., a documentation/film layer or the like), rather than to the actual design of a PCB layer.

It is to be understood and appreciated that, although one or more of FIGS. 1A and 2A-2E might be described above as pertaining to various processes and/or actions that are performed in a particular order, some of these processes and/or actions may occur in different orders and/or concurrently with other processes and/or actions from what is depicted and described above. Moreover, not all of these processes and/or actions may be required to implement the systems and/or methods described herein. Furthermore, while various systems, components, equipment, etc. may have been illustrated in FIG. 1A as separate systems, components, equipment, etc., it will be appreciated that multiple systems, components, equipment, etc. can be implemented as a single system, component, equipment, etc., or a single system, component, equipment, etc. can be implemented as multiple systems, components, equipment, etc. Additionally, functions described as being performed by one system, component, equipment, etc. may be performed by multiple systems, components, equipment, etc., or functions described as being performed by multiple systems, components, equipment, etc. may be performed by a single system, component, equipment, etc.

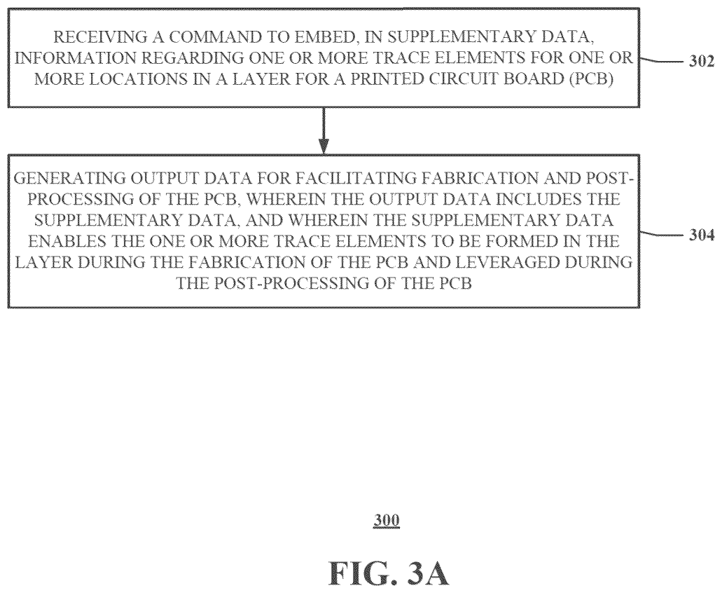

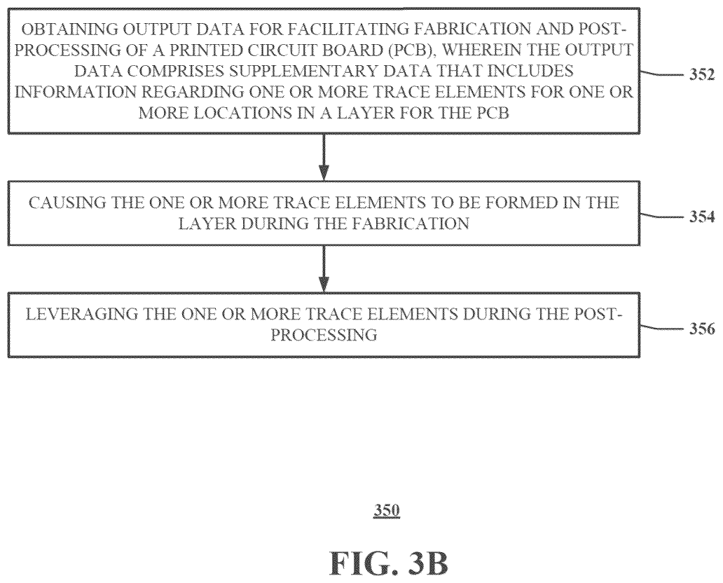

FIG. 3A depicts an illustrative embodiment of a method 300 in accordance with various aspects described herein.

At 302, the method may include receiving a command to embed, in supplementary data, information regarding one or more trace elements for one or more locations in a layer for a printed circuit board (PCB). For example, similar to that described above, a PCB design system/tool may perform one or more operations that include receiving a command to embed, in supplementary data, information regarding one or more trace elements for one or more locations in a layer for a printed circuit board (PCB).

At 304, the method may include generating output data for facilitating fabrication and post-processing of the PCB, wherein the output data includes the supplementary data, and wherein the supplementary data enables the one or more trace elements to be formed in the layer during the fabrication of the PCB and leveraged during the post-processing of the PCB. For example, similar to that described above, a PCB design system/tool may perform one or more operations that include generating output data for facilitating fabrication and post-processing of the PCB, wherein the output data includes the supplementary data, and wherein the supplementary data enables the one or more trace elements to be formed in the layer during the fabrication of the PCB and leveraged during the post-processing of the PCB.

While for purposes of simplicity of explanation, the respective processes are shown and described as a series of blocks in FIG. 3A, it is to be understood and appreciated that the claimed subject matter is not limited by the order of the blocks, as some blocks may occur in different orders and/or concurrently with other blocks from what is depicted and described herein. Moreover, not all illustrated blocks may be required to implement the methods described herein.

FIG. 3B depicts an illustrative embodiment of a method 350 in accordance with various aspects described herein.

At 352, the method may include obtaining output data for facilitating fabrication and post-processing of a printed circuit board (PCB), wherein the output data comprises supplementary data that includes information regarding one or more trace elements for one or more locations in a layer for the PCB. For example, similar to that described above, a fabricator 20 (e.g., the CAD-to-CAM system 22 and/or manufacturing/processing equipment 24 thereof) may obtain output data for facilitating fabrication and post-processing of a printed circuit board (PCB), wherein the output data comprises supplementary data that includes information regarding one or more trace elements for one or more locations in a layer for the PCB.

At 354, the method may include causing the one or more trace elements to be formed in the layer during the fabrication. For example, similar to that described above, the fabricator 20 (e.g., the CAD-to-CAM system 22 and/or the manufacturing/processing equipment 24 thereof) may cause the one or more trace elements to be formed in the layer during the fabrication.

At 356, the method may include leveraging the one or more trace elements during the post-processing. For example, similar to that described above, the fabricator 20 (e.g., the CAD-to-CAM system 22, the manufacturing/processing equipment 24, and/or the testing/validation equipment 26 thereof) may leverage the one or more trace elements during the post-processing.

While for purposes of simplicity of explanation, the respective processes are shown and described as a series of blocks in FIG. 3B, it is to be understood and appreciated that the claimed subject matter is not limited by the order of the blocks, as some blocks may occur in different orders and/or concurrently with other blocks from what is depicted and described herein. Moreover, not all illustrated blocks may be required to implement the methods described herein.

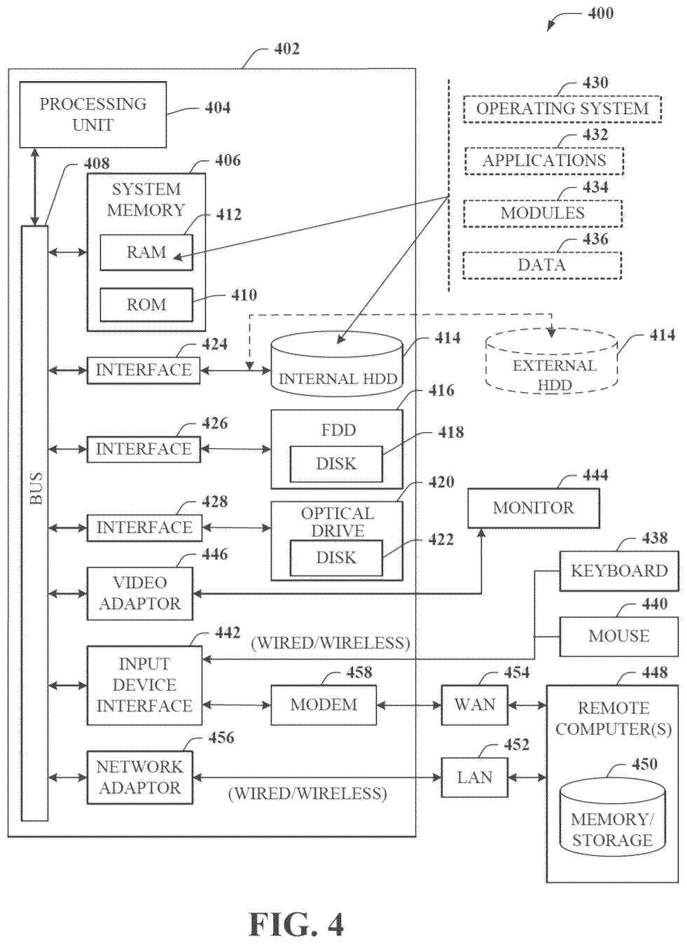

Turning now to FIG. 4, there is illustrated a block diagram of a computing environment in accordance with various aspects described herein. In order to provide additional context for various embodiments of the embodiments described herein, FIG. 4 and the following discussion are intended to provide a brief, general description of a suitable computing environment 400 in which the various embodiments of the subject disclosure can be implemented. For example, computing environment 400 can facilitate, in whole or in part.

Generally, program modules comprise routines, programs, components, data structures, etc., that perform particular tasks or implement particular abstract data types. Moreover, those skilled in the art will appreciate that the methods can be practiced with other computer system configurations, comprising single-processor or multiprocessor computer systems, minicomputers, mainframe computers, as well as personal computers, hand-held computing devices, microprocessor-based or programmable consumer electronics, and the like, each of which can be operatively coupled to one or more associated devices.

As used herein, a processing circuit includes one or more processors as well as other application specific circuits such as an application specific integrated circuit, digital logic circuit, state machine, programmable gate array or other circuit that processes input signals or data and that produces output signals or data in response thereto. It should be noted that while any functions and features described herein in association with the operation of a processor could likewise be performed by a processing circuit.

The illustrated embodiments of the embodiments herein can be also practiced in distributed computing environments where certain tasks are performed by remote processing devices that are linked through a communications network. In a distributed computing environment, program modules can be located in both local and remote memory storage devices.

Computing devices typically comprise a variety of media, which can comprise computer-readable storage media and/or communications media, which two terms are used herein differently from one another as follows. Computer-readable storage media can be any available storage media that can be accessed by the computer and comprises both volatile and nonvolatile media, removable and non-removable media. By way of example, and not limitation, computer-readable storage media can be implemented in connection with any method or technology for storage of information such as computer-readable instructions, program modules, structured data or unstructured data.

Computer-readable storage media can comprise, but are not limited to, random access memory (RAM), read only memory (ROM), electrically erasable programmable read only memory (EEPROM), flash memory or other memory technology, compact disk read only memory (CD ROM), digital versatile disk (DVD) or other optical disk storage, magnetic cassettes, magnetic tape, magnetic disk storage or other magnetic storage devices or other tangible and/or non-transitory media which can be used to store desired information. In this regard, the terms “tangible” or “non-transitory” herein as applied to storage, memory or computer-readable media, are to be understood to exclude only propagating transitory signals per se as modifiers and do not relinquish rights to all standard storage, memory or computer-readable media that are not only propagating transitory signals per se.

Computer-readable storage media can be accessed by one or more local or remote computing devices, e.g., via access requests, queries or other data retrieval protocols, for a variety of operations with respect to the information stored by the medium.

Communications media typically embody computer-readable instructions, data structures, program modules or other structured or unstructured data in a data signal such as a modulated data signal, e.g., a carrier wave or other transport mechanism, and comprises any information delivery or transport media. The term “modulated data signal” or signals refers to a signal that has one or more of its characteristics set or changed in such a manner as to encode information in one or more signals. By way of example, and not limitation, communication media comprise wired media, such as a wired network or direct-wired connection, and wireless media such as acoustic, RF, infrared and other wireless media.

With reference again to FIG. 4, the example environment can comprise a computer 402, the computer 402 comprising a processing unit 404, a system memory 406 and a system bus 408. The system bus 408 couples system components including, but not limited to, the system memory 406 to the processing unit 404. The processing unit 404 can be any of various commercially available processors. Dual microprocessors and other multiprocessor architectures can also be employed as the processing unit 404.

The system bus 408 can be any of several types of bus structure that can further interconnect to a memory bus (with or without a memory controller), a peripheral bus, and a local bus using any of a variety of commercially available bus architectures. The system memory 406 comprises ROM 410 and RAM 412. A basic input/output system (BIOS) can be stored in a non-volatile memory such as ROM, erasable programmable read only memory (EPROM), EEPROM, which BIOS contains the basic routines that help to transfer information between elements within the computer 402, such as during startup. The RAM 412 can also comprise a high-speed RAM such as static RAM for caching data.

The computer 402 further comprises an internal hard disk drive (HDD) 414 (e.g., EIDE, SATA), which internal HDD 414 can also be configured for external use in a suitable chassis (not shown), a magnetic floppy disk drive (FDD) 416, (e.g., to read from or write to a removable diskette 418) and an optical disk drive 420, (e.g., reading a CD-ROM disk 422 or, to read from or write to other high-capacity optical media such as the DVD). The HDD 414, magnetic FDD 416 and optical disk drive 420 can be connected to the system bus 408 by a hard disk drive interface 424, a magnetic disk drive interface 426 and an optical drive interface 428, respectively. The hard disk drive interface 424 for external drive implementations comprises at least one or both of Universal Serial Bus (USB) and Institute of Electrical and Electronics Engineers (IEEE) 1394 interface technologies. Other external drive connection technologies are within contemplation of the embodiments described herein.

The drives and their associated computer-readable storage media provide nonvolatile storage of data, data structures, computer-executable instructions, and so forth. For the computer 402, the drives and storage media accommodate the storage of any data in a suitable digital format. Although the description of computer-readable storage media above refers to a hard disk drive (HDD), a removable magnetic diskette, and a removable optical media such as a CD or DVD, it should be appreciated by those skilled in the art that other types of storage media which are readable by a computer, such as zip drives, magnetic cassettes, flash memory cards, cartridges, and the like, can also be used in the example operating environment, and further, that any such storage media can contain computer-executable instructions for performing the methods described herein.

A number of program modules can be stored in the drives and RAM 412, comprising an operating system 430, one or more application programs 432, other program modules 434 and program data 436. All or portions of the operating system, applications, modules, and/or data can also be cached in the RAM 412. The systems and methods described herein can be implemented utilizing various commercially available operating systems or combinations of operating systems.

A user can enter commands and information into the computer 402 through one or more wired/wireless input devices, e.g., a keyboard 438 and a pointing device, such as a mouse 440. Other input devices (not shown) can comprise a microphone, an infrared (IR) remote control, a joystick, a game pad, a stylus pen, touch screen or the like. These and other input devices are often connected to the processing unit 404 through an input device interface 442 that can be coupled to the system bus 408, but can be connected by other interfaces, such as a parallel port, an IEEE 1394 serial port, a game port, a universal serial bus (USB) port, an IR interface, etc.

A monitor 444 or other type of display device can be also connected to the system bus 408 via an interface, such as a video adapter 446. It will also be appreciated that in alternative embodiments, a monitor 444 can also be any display device (e.g., another computer having a display, a smart phone, a tablet computer, etc.) for receiving display information associated with computer 402 via any communication means, including via the Internet and cloud-based networks. In addition to the monitor 444, a computer typically comprises other peripheral output devices (not shown), such as speakers, printers, etc.

The computer 402 can operate in a networked environment using logical connections via wired and/or wireless communications to one or more remote computers, such as a remote computer(s) 448. The remote computer(s) 448 can be a workstation, a server computer, a router, a personal computer, portable computer, microprocessor-based entertainment appliance, a peer device or other common network node, and typically comprises many or all of the elements described relative to the computer 402, although, for purposes of brevity, only a remote memory/storage device 450 is illustrated. The logical connections depicted comprise wired/wireless connectivity to a local area network (LAN) 452 and/or larger networks, e.g., a wide area network (WAN) 454. Such LAN and WAN networking environments are commonplace in offices and companies, and facilitate enterprise-wide computer networks, such as intranets, all of which can connect to a global communications network, e.g., the Internet.

When used in a LAN networking environment, the computer 402 can be connected to the LAN 452 through a wired and/or wireless communication network interface or adapter 456. The adapter 456 can facilitate wired or wireless communication to the LAN 452, which can also comprise a wireless AP disposed thereon for communicating with the adapter 456.

When used in a WAN networking environment, the computer 402 can comprise a modem 458 or can be connected to a communications server on the WAN 454 or has other means for establishing communications over the WAN 454, such as by way of the Internet. The modem 458, which can be internal or external and a wired or wireless device, can be connected to the system bus 408 via the input device interface 442. In a networked environment, program modules depicted relative to the computer 402 or portions thereof, can be stored in the remote memory/storage device 450. It will be appreciated that the network connections shown are example and other means of establishing a communications link between the computers can be used.

The computer 402 can be operable to communicate with any wireless devices or entities operatively disposed in wireless communication, e.g., a printer, scanner, desktop and/or portable computer, portable data assistant, communications satellite, any piece of equipment or location associated with a wirelessly detectable tag (e.g., a kiosk, news stand, restroom), and telephone. This can comprise Wireless Fidelity (Wi-Fi) and BLUETOOTH® wireless technologies. Thus, the communication can be a predefined structure as with a conventional network or simply an ad hoc communication between at least two devices.

Wi-Fi can allow connection to the Internet from a couch at home, a bed in a hotel room or a conference room at work, without wires. Wi-Fi is a wireless technology similar to that used in a cell phone that enables such devices, e.g., computers, to send and receive data indoors and out; anywhere within the range of a base station. Wi-Fi networks use radio technologies called IEEE 802.11 (a, b, g, n, ac, ag, etc.) to provide secure, reliable, fast wireless connectivity. A Wi-Fi network can be used to connect computers to each other, to the Internet, and to wired networks (which can use IEEE 802.3 or Ethernet). Wi-Fi networks operate in the unlicensed 2.4 and 5 GHz radio bands for example or with products that contain both bands (dual band), so the networks can provide real-world performance similar to the basic 10BaseT wired Ethernet networks used in many offices.

What has been described above includes mere examples of various embodiments. It is, of course, not possible to describe every conceivable combination of components or methodologies for purposes of describing these examples, but one of ordinary skill in the art can recognize that many further combinations and permutations of the present embodiments are possible. Accordingly, the embodiments disclosed and/or claimed herein are intended to embrace all such alterations, modifications and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim. It is also to be understood and appreciated that the subject matter in one or more dependent claims may be combined with that in one or more other dependent claims.

Computing devices typically comprise a variety of media, which can comprise computer-readable storage media and/or communications media, which two terms are used herein differently from one another as follows. Computer-readable storage media can be any available storage media that can be accessed by the computer and comprises both volatile and nonvolatile media, removable and non-removable media. By way of example, and not limitation, computer-readable storage media can be implemented in connection with any method or technology for storage of information such as computer-readable instructions, program modules, structured data or unstructured data. Computer-readable storage media can comprise the widest variety of storage media including tangible and/or non-transitory media which can be used to store desired information. In this regard, the terms “tangible” or “non-transitory” herein as applied to storage, memory or computer-readable media, are to be understood to exclude only propagating transitory signals per se as modifiers and do not relinquish rights to all standard storage, memory or computer-readable media that are not only propagating transitory signals per se.

In addition, a flow diagram may include a “start” and/or “continue” indication. The “start” and “continue” indications reflect that the steps presented can optionally be incorporated in or otherwise used in conjunction with other routines. In this context, “start” indicates the beginning of the first step presented and may be preceded by other activities not specifically shown. Further, the “continue” indication reflects that the steps presented may be performed multiple times and/or may be succeeded by other activities not specifically shown. Further, while a flow diagram indicates a particular ordering of steps, other orderings are likewise possible provided that the principles of causality are maintained.

As may also be used herein, the term(s) “operably coupled to”, “coupled to”, and/or “coupling” includes direct coupling between items and/or indirect coupling between items via one or more intervening items. Such items and intervening items include, but are not limited to, junctions, communication paths, components, circuit elements, circuits, functional blocks, and/or devices. As an example of indirect coupling, a signal conveyed from a first item to a second item may be modified by one or more intervening items by modifying the form, nature or format of information in a signal, while one or more elements of the information in the signal are nevertheless conveyed in a manner than can be recognized by the second item. In a further example of indirect coupling, an action in a first item can cause a reaction on the second item, as a result of actions and/or reactions in one or more intervening items.

Although specific embodiments have been illustrated and described herein, it should be appreciated that any arrangement which achieves the same or similar purpose may be substituted for the embodiments described or shown by the subject disclosure. The subject disclosure is intended to cover any and all adaptations or variations of various embodiments. Combinations of the above embodiments, and other embodiments not specifically described herein, can be used in the subject disclosure. For instance, one or more features from one or more embodiments can be combined with one or more features of one or more other embodiments. In one or more embodiments, features that are positively recited can also be negatively recited and excluded from the embodiment with or without replacement by another structural and/or functional feature. The steps or functions described with respect to the embodiments of the subject disclosure can be performed in any order. The steps or functions described with respect to the embodiments of the subject disclosure can be performed alone or in combination with other steps or functions of the subject disclosure, as well as from other embodiments or from other steps that have not been described in the subject disclosure. Further, more than or less than all of the features described with respect to an embodiment can also be utilized.

What is claimed is:

1. A device, comprising:
a processing system including a processor; and
a memory that stores executable instructions that, when executed by the processing system, facilitate performance of operations, the operations comprising:
receiving a command to embed, in supplementary data, information regarding one or more trace elements for one or more locations in a layer for a printed circuit board (PCB); and
generating output data for facilitating fabrication and post-processing of the PCB,
wherein the output data includes the supplementary data, and
wherein the supplementary data enables the one or more trace elements to be formed in the layer during the fabrication of the PCB and leveraged during the post-processing of the PCB.

2. The device of claim 1, wherein the supplementary data comprises a film record associated with the layer.

3. The device of claim 1, wherein the one or more locations correspond to one or more through-hole vias in the layer that are to be backdrilled.

4. The device of claim 1, wherein the post-processing comprises backdrilling.

5. The device of claim 1, wherein the processing system is associated with a PCB design system that provides user selectable options for inputting the information and submitting the command.

6. The device of claim 1, wherein the layer comprises a ground layer.

7. The device of claim 6, wherein the one or more trace elements, when positioned in the layer, electrically couple one or more signal layers of the PCB to the ground layer.

8. The device of claim 1, wherein the output data further includes design data for the layer, and wherein the information is not included in or is distinct from the design data.

9. The device of claim 1, wherein the output data further includes fabrication data that includes design data for the layer.

10. The device of claim 1, wherein the output data further includes a design netlist that corresponds to design data for the layer, and a supplemental instruction or guide for instructing a fabricator to use the supplementary data to resolve any mismatch between the design netlist and a netlist that is generated from the design data, thereby facilitating formation of the one or more trace elements in the layer during the fabrication.

11. The device of claim 1, wherein the information comprises one or more graphics that correspond to the one or more trace elements.

12. The device of claim 1, wherein the information specifies a minimum distance between the one or more elements and a defined must not cut layer of the PCB.

13. The device of claim 1, wherein the leveraging involves resistive testing using the one or more trace elements.

14. The device of claim 1, wherein the supplementary data comprises a film layer associated with a padstack.

15. A non-transitory machine-readable medium, comprising executable instructions that, when executed by a processing system including a processor, facilitate performance of operations, the operations comprising:
receiving a command to embed, in supplementary data, information regarding one or more trace elements for one or more locations in a layer for a printed circuit board (PCB); and
generating output data for facilitating fabrication and post-processing of the PCB,
wherein the output data includes the supplementary data, and
wherein the supplementary data enables the one or more trace elements to be formed in the layer during the fabrication of the PCB and leveraged during the post-processing of the PCB.

16. The non-transitory machine-readable medium of claim 15, wherein the supplementary data comprises a film record associated with the layer.

17. The non-transitory machine-readable medium of claim 15, wherein the post-processing comprises backdrilling.

18. A method, comprising:
obtaining output data for facilitating fabrication and post-processing of a printed circuit board (PCB), wherein the output data comprises supplementary data that includes information regarding one or more trace elements for one or more locations in a layer for the PCB;
causing the one or more trace elements to be formed in the layer during the fabrication; and
leveraging the one or more trace elements during the post-processing.

19. The method of claim 18, wherein the output data further includes design data for the layer, and wherein the information is not included in or is distinct from the design data.

20. The method of claim 18, wherein the information comprises one or more graphics that correspond to the one or more trace elements.

21. A printed circuit board (PCB) that comprises one or more trace elements formed in one or more locations in a layer of the PCB, the PCB being fabricated in accordance with output data that includes supplementary data, the supplementary data identifying the one or more trace elements to be formed in the one or more locations in the layer, and the one or more trace elements being usable to facilitate post-processing of the PCB.

22. The PCB of claim 21, wherein the output data further includes design data for the layer, and wherein the supplementary data is not included in or is distinct from the design data.
